(19) United States
(12) Patent Application Publication
(10) Pub. No.: US 2026/0040526 A1
(43) Pub. Date: Feb. 5, 2026

(54) CAPACITOR-BASED MEMORY AND METHOD OF MANUFACTURING THE SAME

(71) Applicant: Winbond Electronics Corp., Taichung City (TW)

(72) Inventor: Huang-Nan CHEN, Taichung City (TW)

(21) Appl. No.: 19/288,634

(22) Filed: Aug. 1, 2025

(30) Foreign Application Priority Data
Aug. 2, 2024 (TW) 113128969

(51) Int. Cl. H10B 12/00

(52) U.S. Cl. CPC H10B 12/315; H10B 12/0335; H10B 12/34; H10B 12/482; H10B 12/485

(57) ABSTRACT

A capacitor-based memory includes: a substrate; bit lines disposed on the substrate; insulating structures disposed on the substrate and located between neighboring bit lines, wherein a bottom portion of each insulating structure has two cavities facing each other along an extending direction of each bit line; a capacitor contact disposed on the substrate and located in a through hole between neighboring insulating structures; a first dielectric layer disposed on a sidewall of the through hole above the cavities and located between each insulating structure and the capacitor contact; and a second dielectric layer including a first portion and a second portion. The first portion is disposed on the first dielectric layer and located between the first dielectric layer and the capacitor contact. The second portion is disposed in the cavities and located between the bottom portion of each insulating structure and the capacitor contact.

### CROSS REFERENCE TO RELATED APPLICATIONS

This application claims priority of Taiwan Patent Application No. 113128969, filed Aug. 2, 2024, the entirety of which is incorporated by reference herein.

### TECHNICAL FIELD

The present disclosure relates to a capacitor-based memory and method of manufacturing the same, and in particular, to a capacitor contact of the capacitor-based memory and method of manufacturing the same.

### BACKGROUND

As capacitor-based memories like DRAM become more integrated, the dimensions and the pitches of the capacitor contact (CC) used for connecting the substrate and the capacitor have also been shrunk, causing the aspect ratio of the capacitor contact to increase. Thus, the alignment margin of the capacitor contact during the lithography process has decreased, and the resistance of the capacitor contact has increased. Furthermore, the insulating material located on the bottom sidewall of the trench may be thinned or damaged during the etching process that forms the trench, which is to be filled with the capacitor contact material. This may cause electrical shorting or crosstalk between the subsequently filled capacitor contacts. The performance and the manufacturing yield of the capacitor-based memory may be degraded.

To address this issue, increasing the thickness of the insulating material on the trench sidewalls is a method applied in current capacitor-based memory. However, this solution can increase capacitor contact resistance if the overall structural size is unchanged. Maintaining the same resistance becomes challenging when scaling down the capacitor-based memory.

In other current capacitor-based memory, a capacitor contact hole may be formed in the insulating layer between the bit lines, with its base expanding toward the bit lines so the capacitor contact overlaps the bit lines in the vertical projection. However, the capacitor contact hole expanding toward the bit lines has restricted the area of the bit line contact. Not only has the resistance of the bit line contact increased, the risk for the bit line contact to collapse has also increased. Furthermore, the capacitor contact hole expanding toward the bit lines has also allowed the bit line contact to be closer to the capacitor contact. The parasitic capacitance between the bit line contact and the capacitor contact may be increased, and the risk of leakage may also be increased. Thus, there remain some issues regarding the capacitor-based memory and manufacturing technique that need to be overcame.

### BRIEF SUMMARY

The present disclosure proposes a capacitor-based memory and a method of manufacturing the same. The electrical shorting or crosstalk between adjacent capacitor contacts may be improved without affecting the design of the bit line contact. The issue of the capacitor contact interfering with the bit line contact may be eliminated as well.

An embodiment of the present disclosure provides a capacitor-based memory. The capacitor-based memory includes: a substrate; bit lines disposed on the substrate; insulating structures disposed on the substrate and located between neighboring bit lines, wherein a bottom portion of each insulating structure has two cavities facing each other along an extending direction of each bit line; a capacitor contact disposed on the substrate and located in a through hole between neighboring insulating structures; a first dielectric layer disposed on a sidewall of the through hole above the cavities and located between each insulating structure and the capacitor contact; and a second dielectric layer including a first portion and a second portion. The first portion is disposed on the first dielectric layer and located between the first dielectric layer and the capacitor contact. The second portion is disposed in the cavities and located between the bottom portion of each insulating structure and the capacitor contact.

Another embodiment of the present disclosure provides a method of manufacturing a capacitor-based memory. The method includes forming bit lines on a substrate, and forming insulating structures on the substrate between neighboring bit lines. A bottom portion of each insulating structure has two cavities facing each other along an extending direction of each bit line. The method further includes forming a capacitor contact on the substrate in a through hole between neighboring insulating structures, conformally forming a first dielectric layer on a sidewall of the through hole above the cavities and between each insulating structure and the capacitor contact, and forming a second dielectric layer including a first portion and a second portion. The first portion is formed on the first dielectric layer between the first dielectric layer and the capacitor contact. The second portion is formed in the cavities between the bottom portion of each insulating structure and the capacitor contact.

### BRIEF DESCRIPTION OF THE DRAWINGS

The present disclosure can be more fully understood by reading the subsequent detailed description and examples with references made to the accompanying drawings, wherein:

FIGS. 1-11 illustrate cross-sectional views of various intermediate stages of manufacturing a capacitor-based memory, according to an embodiment of the present disclosure;

FIG. 12 illustrates a three-dimensional view of a capacitor-based memory, according to an embodiment of the present disclosure;

FIG. 13 illustrates a top view of a capacitor-based memory, according to an embodiment of the present disclosure;

FIGS. 14-17 illustrate cross-sectional views of various intermediate stages of manufacturing a capacitor-based memory, according to another embodiment of the present disclosure; and

FIGS. 18-20 illustrate cross-sectional views of various intermediate stages of manufacturing a capacitor-based memory, according to yet another embodiment of the present disclosure.

### DETAILED DESCRIPTION

This disclosure presents multiple possible embodiments for implementing features of the subject matter without limitation. For example, a first feature may be in direct contact with a second feature, or additional elements may exist between them. Steps described can occur in various orders, and some features may be replaced or omitted as needed. Reference numerals or letters may be repeated for clarity and do not imply specific relationships among embodiments.

According to the present disclosure, two cavities may be formed in the bottom portion of the insulating structure before the formation of the capacitor contact. These cavities may face each other along the extending direction of the bit line, allowing the second dielectric layer to remain undamaged during the subsequent etching. This helps preventing short circuitry or interference between neighboring capacitor contacts. Furthermore, in some embodiments, each capacitor contact may have single-sided protruding portion filled into the cavity, which in turn reduces the resistance thereof. Therefore, the reliability and the operating speed of the capacitor-based memory may be enhanced. The capacitor-based memory described herein may be referred to a dynamic random access memory (DRAM), but the present disclosure is not limited thereto.

It should be noted, during the capacitor-based memory operation, a sufficient sense margin between the stored “0” and “1” states is required for proper operation of the sense amplifier. According to the formula of the sense margin, as the parasitic capacitance between the bit line contact and the capacitor contact becomes smaller, the value of the sense margin becomes larger. Since the expanding direction of the cavity of the present disclosure is parallel to the extending direction of the bit line, the parasitic capacitance between the bit line contact and the capacitor contact may be reduced. In other words, the present disclosure may allow the “0” state and the “1” state to be determined more effectively, thereby enhancing the performance of the capacitor-based memory.

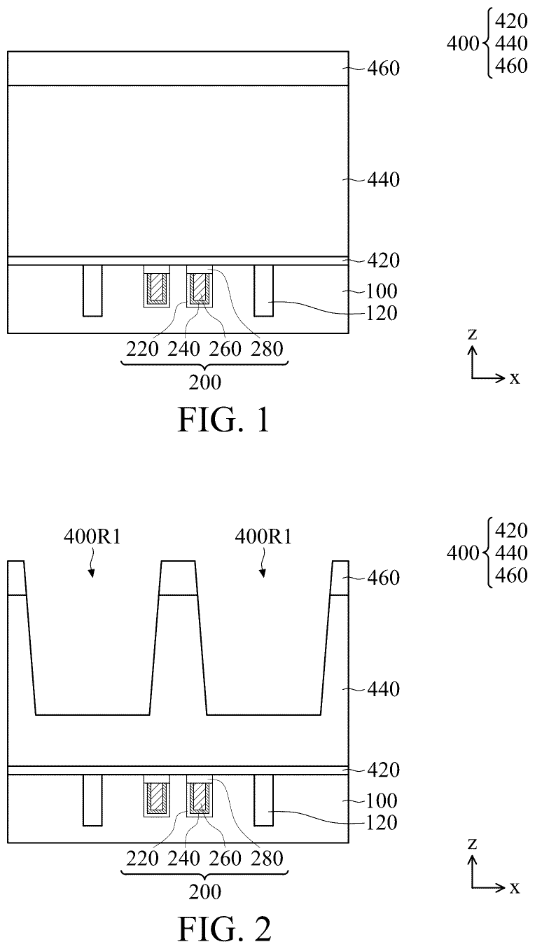

FIGS. 1-11 illustrate cross-sectional views of various intermediate stages of manufacturing a capacitor-based memory 10, according to an embodiment of the present disclosure. In the present embodiment, only a portion of the capacitor-based memory is illustrated. The remaining portions of the capacitor-based memory may be formed from any known structure or method.

Referring to FIG. 1, the capacitor-based memory 10 may include a substrate 100, a shallow trench isolation structure 120 and word lines 200 formed in the substrate 100, and an insulating material layer 400 formed on the substrate 100. In an embodiment, the word lines 200 may include a dielectric layer 220, a barrier layer 240, a conductive filling 260, and a capping layer 280. Moreover, the insulating material layer 400 may include a liner 420, an insulating layer 440, and an insulating layer 460. The insulating layer 440 is located between the liner 420 and the insulating layer 460. The shallow trench isolation structure 120 may electrically isolate active areas (AA) in the substrate 100. Any known method and structure may be adopted to form the substrate 100, the shallow trench isolation structure 120, and the word lines 200, and the details are not described again herein.

In some embodiment, the substrate 100 may be a semiconductor substrate, for example, silicon (Si) substrate. Furthermore, the semiconductor substrate may be an elemental semiconductor including germanium (Ge), a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy, or a combination thereof. In some embodiments, the substrate 100 may be a semiconductor on insulator (SOI) substrate.

Furthermore, the substrate 100 may include p-type doping regions and/or n-type doing regions (not shown) formed by for example, ion implantation and/or diffusion process.

In some embodiments, materials of the dielectric layer 220 may include high-k oxides, such as hafnium (IV) oxide, hafnium silicate (HfSiO₄), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (La₂O₃), aluminum oxide (Al₂O₃), aluminum silicon oxide (AlSiO), zirconium (IV) oxide, titanium oxide (TiO), tantalum oxide (Ta₂O₅), yttrium oxide (Y₂O₃), silicon oxynitride (SiON), or the like. Materials of the barrier layer 240 may include tantalum nitride (TaN), nickel silicide (NiSi), cobalt silicide (CoSi), titanium nitride (TiN), tungsten nitride (WN), tungsten carbonitride (WCN), titanium aluminum (TiAl), titanium tantalum nitride (TiTaN), titanium aluminum nitride (TiAlN), tantalum carbonitride (TaCN), tantalum carbide (TaC), tantalum silicon nitride (TaSiN), or the like. Materials of the conductive filling 260 may include amorphous silicon, polysilicon, poly-Ge, poly-SiGe, metal nitride, metal silicide, metal carbide, metal oxide, or metals. Metals may include cobalt (Co), ruthenium (Ru), aluminum (Al), palladium (Pd), platinum (Pt), tungsten (W), copper (Cu), titanium (Ti), tantalum (Ta), silver (Ag), gold (Au), or nickel (Ni). The material of the conductive filling 260 may include tungsten. Materials of the capping layer 280 may include nitrides, such as silicon nitride (SiN), silicon oxynitride, silicon carbonitride (SiCN), or silicon oxynitrocarbide (SiOCN).

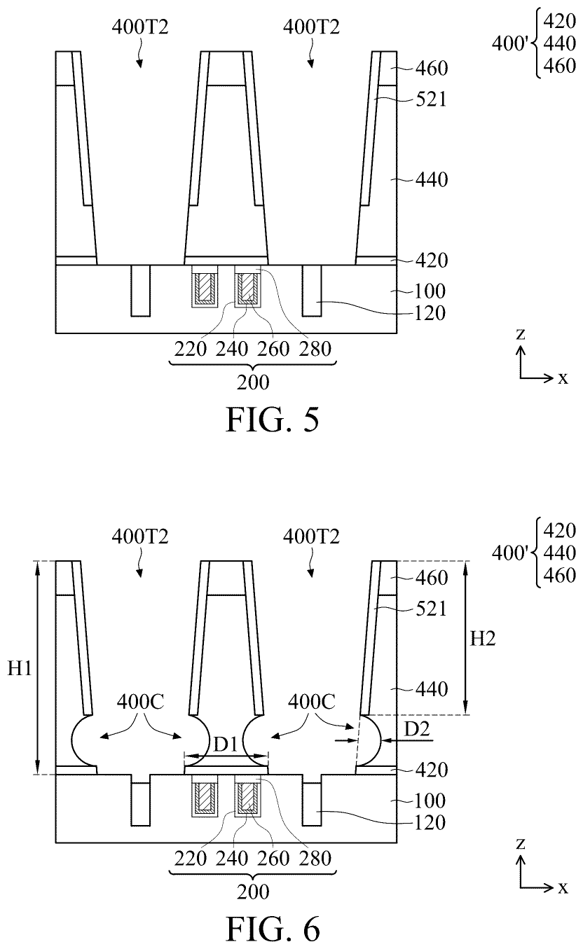

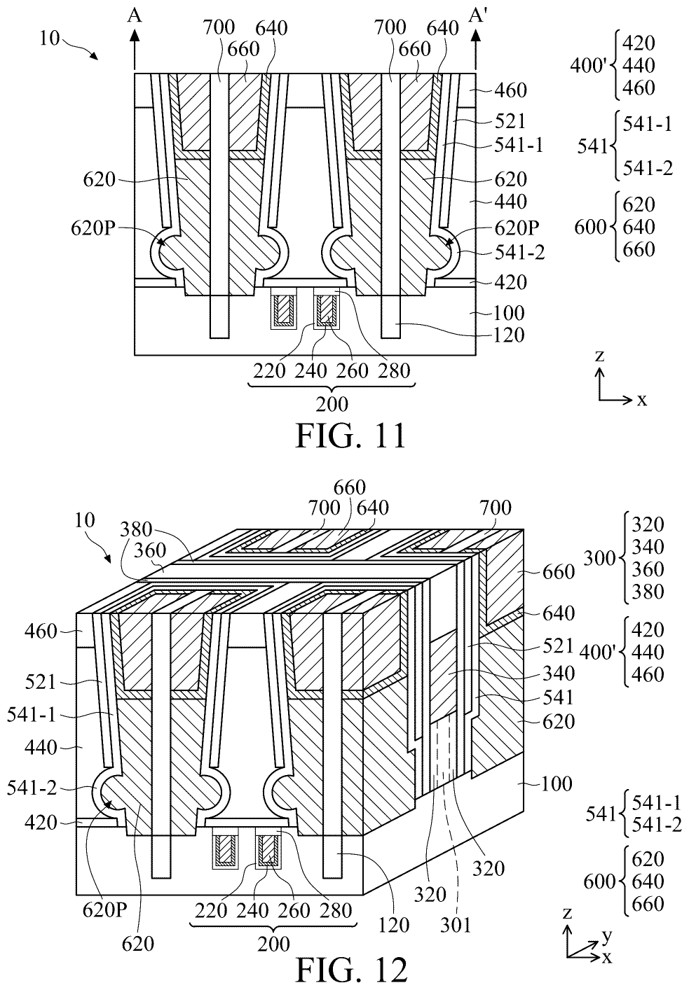

In some embodiments, materials of the liner 420 may be for example, silicon nitride. The insulating layer 440 may include spin-on dielectric (SOD), for example, spin-on glass (SOG) or other flowable oxides. In some embodiments, materials of the insulating layer 460 may include tetra ethyl ortho silicate (TEOS) or the like. Since a through hole 400T2 (shown in FIG. 5) may be subsequently formed in the insulating material layer 400 for filling a capacitor contact 600 (shown in FIG. 11), increasing the planarization of the insulating layer 400 may help improving the stability of the overall structure. The spin-on dielectric may be used to form the insulating layer 440 to increase the surface planarization. In an embodiment not shown, the insulating layer 440 does not apply spin-on dielectric or spin-on glass, and the disposition of the liner 420 may be omitted.

In an embodiment, the planarization process, such as chemical mechanical polish (CMP), may be performed on the top surface of the insulating material layer 400 to enhance the planarization of the top surface of the insulating material layer 400. The manufacturing yield of the subsequently formed capacitor contact 600 may be improved.

Furthermore, in addition to the materials mentioned previously, the materials of the insulating material layer 400 may be selected from silicon oxide (SiO), silicon oxynitride, silicon oxycarbonitride, undoped silicate glass (USG), doped silicon oxide (such as boron-doped phosphosilicate glass (BPSG), fused silica glass (FSG), phosphosilicate glass (PSG), boron-doped silicate glass (BSG)), low-k dielectric materials, the like, or a combination thereof.

Referring to FIG. 2, a recess 400R1 may be formed in the insulating material layer 400. It should be noted that the bottom surface of the recess 400R1 of the present disclosure is higher than the bottom surface of the insulating material layer 400. In other words, the recess 400R1 may not penetrate through the insulating material layer 400, so the substrate 100 is not exposed by the recess 400R1. The present disclosure may more effectively control the critical dimension (CD) of the capacitor contact 600 (to be described in detail below) by forming the recess 400R1 that does not penetrate through the insulating material layer 400. Also, the bottom portion of the insulating material layer 400 may be protected. The recess 400R1 may be located between neighboring bit lines 300 (to be described in detail below) from top view. The recess 400R1 may not overlap the bit lines 300. The depth of the recess 400R1 may be greater than or equal to half of the thickness of the insulating material layer 400. The recess 400R1 may be formed by any suitable etching process. For example, the recess 400R1 may be formed using the anisotropic etching process (such as dry etching). Next, the isotropic etching process (such as wet etching) may be adopted to adjust the critical dimension of the recess 400R1. In some embodiments, one or more cycles of the etching process may be performed until the recess 400R1 reaches the desired dimension and depth.

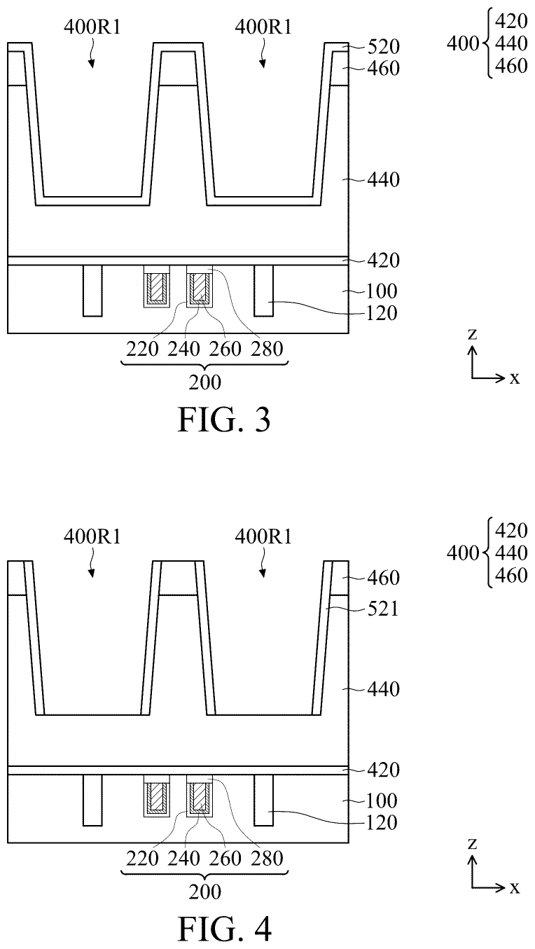

Referring to FIG. 3, a first dielectric material 520 may be conformally formed on the bottom surface and the sidewalls of the recess 400R1. In some embodiments, in addition to lining onto the surface of the recess 400R1, the first dielectric material 520 may also extend onto the top surface of the insulating material layer 400. Materials of the first dielectric material 520 may be similar to those of the capping layer 280.

Referring to FIG. 4, the horizontal portions of the first dielectric material 520 (for example, the portion on the bottom surface of the recess 400R1 and the portion on the top surface of the insulating material layer 400) may be removed to form a first dielectric layer 521 covering only the sidewalls of the recess 400R1. The horizontal portions of the first dielectric material 520 may be etched by the anisotropic etch back process, for example, reactive ion etching (RIE) or plasma etching. The first dielectric layer 521 may function to protect the top portion of the subsequently formed insulating structures 400′, and to prevent the subsequently formed capacitor contact 600 from diffusing into the insulating structures 400′.

If a through hole is formed through the insulating material layer to expose the substrate before the formation of the first dielectric material, the first dielectric material may be formed onto the exposed surface of the substrate. In doing so, the first dielectric material located on the bottom portion of the sidewalls of the through hole may be easily thinned down during the subsequent removal of the horizontal portions of the first dielectric material. In other words, the lower part of the first dielectric layer may be thinner. In particular, the inclined angle of the sidewalls of the through hole increases as the aspect ratio of the through hole becomes larger. This may lead to the lower part of the first dielectric layer to be more severely thinned down or even fractured, resulting into the issue of short circuitry or interference occurring between the subsequently formed capacitor contacts. Therefore, by forming the first dielectric material 520 onto the sidewalls of the recess 400R1 that does not penetrate through the insulating material layer 400, the issue of short circuitry or interference occurring between the subsequently formed capacitor contacts 600 may be effectively prevented.

Referring to FIG. 5, the insulating material layer 400 below the recess 400R1 (or the bottom portion of the insulating material layer 400) may be etched using the first dielectric layer 521 as the mask, extending the recess 400R1 into a through hole 400T2 that exposes the substrate 100. This etching process transforms the remaining insulating material layer 400 into insulating structures 400′. In other words, the bottom surface of the through hole 400T2 is lower than the bottom surface of the first dielectric layer 521. One or more cycles of etching process may be performed until the substrate 100 is exposed. According to some embodiments, since the critical dimension of the recess 400R1 is easy to control, and the first dielectric layer 521 is present for protection, the critical dimension of the through hole 400T2 may also be easy to control. It is worth noted that the recessing of the substrate 100 is not performed in this procedure. The through hole 400T2 may be formed by the anisotropic dry etching.

As mentioned previously, the lower part of the first dielectric layer may be thinner if the first dielectric material is formed on the surface of the through hole exposing the substrate. In this case, the following recessing of the substrate to remove the surface impurities on the substrate may damage the first dielectric layer located on the bottom portion of the sidewalls of the through hole. This may cause the bottom portion of the insulating structure to be eroded, and a breach may be generated. If the breach unintentionally connects neighboring through holes, capacitor contacts may fill the breach and create short circuitry.

Referring FIG. 6, cavities 400C may be formed at the bottom portion of the sidewalls of the through hole 400T2 exposed by the first dielectric layer 521 before the removal of the surface impurities of the substrate 100, according to an embodiment of the present disclosure. As such, the bottom portion of each insulating structure 400′ may have two cavities 400C positioned opposite each other along the extending direction of the bit lines 300.

In some embodiments, the expanding direction of the cavities 400C may be parallel with the extending direction of the bit lines 300, for example along the x-axis (referring to FIG. 12). The cavities 400C may expand into the bottom portion of the insulating structures 400′, and the first dielectric layer 521 may be located above the cavities 400C. In some preferred embodiments, a maximum horizontal depth D2 from the dash line extending from the main surface of the first dielectric layer 521 to the surface of the cavities 400C may be smaller than half of a maximum width D1 of the insulating structures 400′, and may be greater than 5% of the maximum width D1 of the insulating structures 400′. This may further prevent the subsequently formed capacitor contacts 600 from interfering with each other, and may more effectively protect the bottom portion of the insulating structures 400′. Moreover, a height H2 of the first dielectric layer 521 may be greater than or equal to half of a thickness H1 of the insulating structures 400′. In some embodiments, the cavities 400C may be formed using the isotropic wet etching, and the shallow trench isolation structure 120 may be simultaneously recessed to form a recess above the shallow trench isolation structure 120. The substrate 100 is substantially unaffected by the isotropic wet etching.

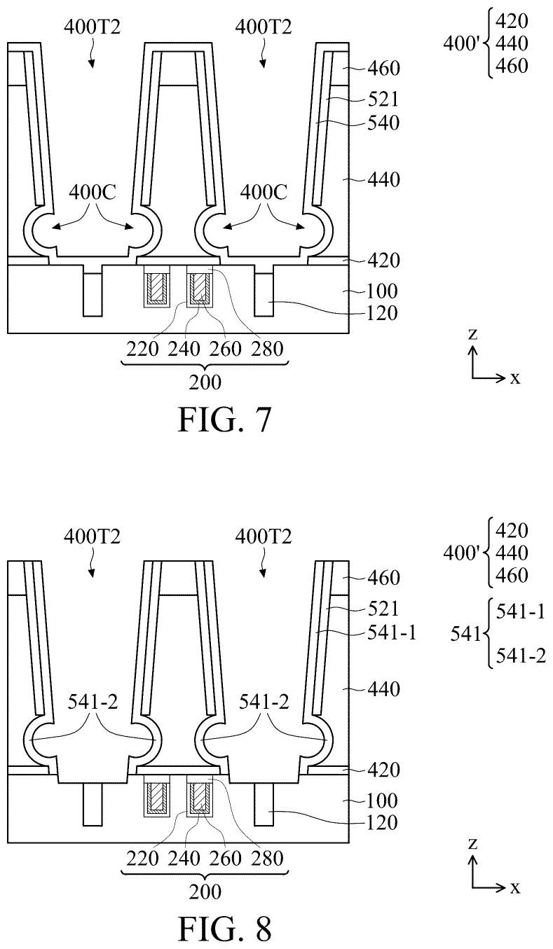

Referring to FIG. 7, a second dielectric material 540 may be conformally deposited on the surface of the through hole 400T2 and the cavities 400C. In some embodiments, in addition to lining onto the surfaces of the through hole 400T2 and the cavities 400C, the second dielectric material 540 may also be conformally formed on the top surface of the insulating structures 400′. Furthermore, the second dielectric material 540 may be filled into the recess above the shallow trench isolation structure 120. In order to enhance the manufacturing efficiency, the thickness of the second dielectric material 540 may not be greater than half of the maximum width D1 of the insulating structures 400′. Materials of the second dielectric material 540 may be similar to those of the capping layer 280. The second dielectric material 540 may be formed using atomic layer deposition (ALD) with superior step coverage.

Referring to FIG. 8, the horizontal portions of the second dielectric material 540 (for example, the portion on the bottom surface of the through hole 400T2, the portion above the shallow trench isolation structure 120, and the portion on the top surface of the insulating structures 400′) may be removed by for example, the anisotropic etch back process to form a second dielectric layer 541. A first portion 541-1 of the second dielectric layer 541 may be formed on the first dielectric layer 521, and a second portion 541-2 of the second dielectric layer 541 may be formed on the cavities 400C.

According to an embodiment, the second portion 541-2 of the second dielectric layer 541 may be protected by the profile of the cavities 400C from the subsequent etching processes (for example, the recessing of the substrate 100). In doing so, the second portion 541-2 of the second dielectric layer 541 may provide excellent protection for the bottom portion of the insulating structures 400′, which in turn may prevent the short circuitry and the interference occurring between the subsequently formed capacitor contacts 600. Furthermore, the present disclosure may increase the flexibility of the structural design and process through the combination of the first dielectric layer 521 and the second dielectric layer 541.

Next, the recessing may be performed on the substrate 100. The substrate 100 may be recessed using the anisotropic etching process that is selective to the substrate 100. The surface impurities of the substrate 100 may be removed, thereby reducing the contact resistivity of the subsequently formed capacitor contacts 600. The second portion 541-2 of the second dielectric layer 541 may not be damaged during the recessing of the substrate 100, since the second portion 541-2 of the second dielectric layer 541 is protected by the profile of the cavities 400C. In some embodiments, the recessed substrate 100 and the remaining shallow trench isolation structure 120 are substantially levelled, allowing the subsequent capacitor contacts 600 to be more easily filled.

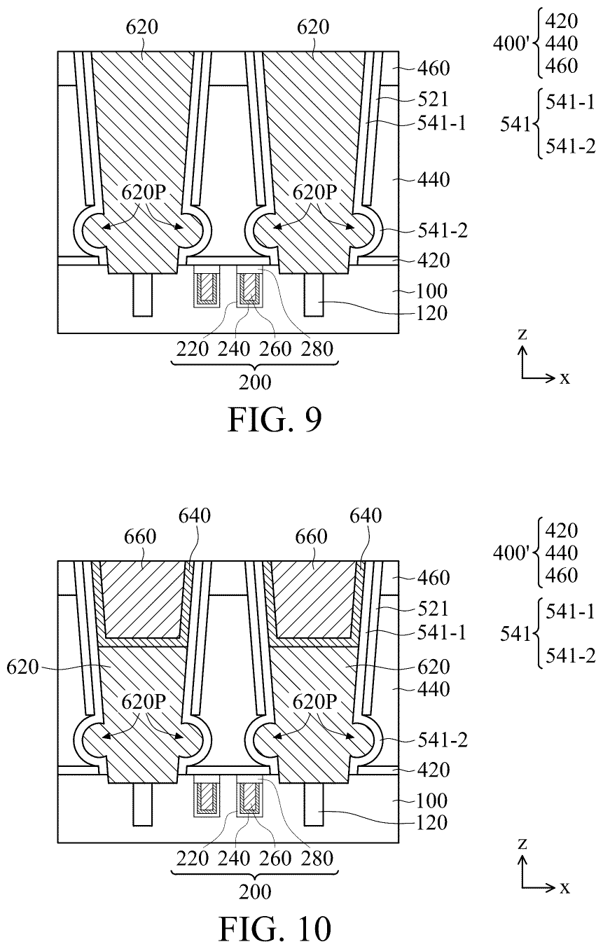

Referring to FIG. 9, a conductive material 620 may be filled into the through hole 400T2. In some embodiments, the conductive material 620 may be further filled into the cavities 400C to form protruding portions 620P. Such configuration may reduce the resistance of the capacitor contact 600, thereby improving the operating speed of the capacitor-based memory 10. In other words, the protruding portions 620P may be embedded into the insulating structures 400′, and the first dielectric layer 521 may be located above the protruding portions 620P. In doing so, the first portion 541-1 of the second dielectric layer 541 may be located between the first dielectric layer 521 and the conductive material 620, and the second portion 541-2 of the second dielectric layer 541 may be located between the insulating structures 400′ and the protruding portions 620P. Furthermore, in the embodiment where the liner 420 is omitted, the protruding portions 620P may directly contact the substrate 100. As such, the contact area between the capacitor contact 600 and the substrate 100 may be further increased, thereby reducing the contact resistance and enhancing the reliability of the capacitor-based memory 10. Materials of the conductive material 620 may include polysilicon, poly-Ge, poly-SiGe, or the like.

Referring to FIG. 10, the capacitor contact material may include the conductive material 620, a barrier layer 640, and a conductive filling 660 sequentially formed, according to an embodiment. A recess may be formed by recessing the top portion of the conductive material 620, followed by conformally forming the barrier layer 640 in the recess. Then, the conductive filling 660 is formed on the barrier layer 640, and the recess is filled. Materials of the barrier layer 640 may be similar to those of the barrier layer 240. Materials of the conductive filling 660 may be similar to those of the conductive filling 260.

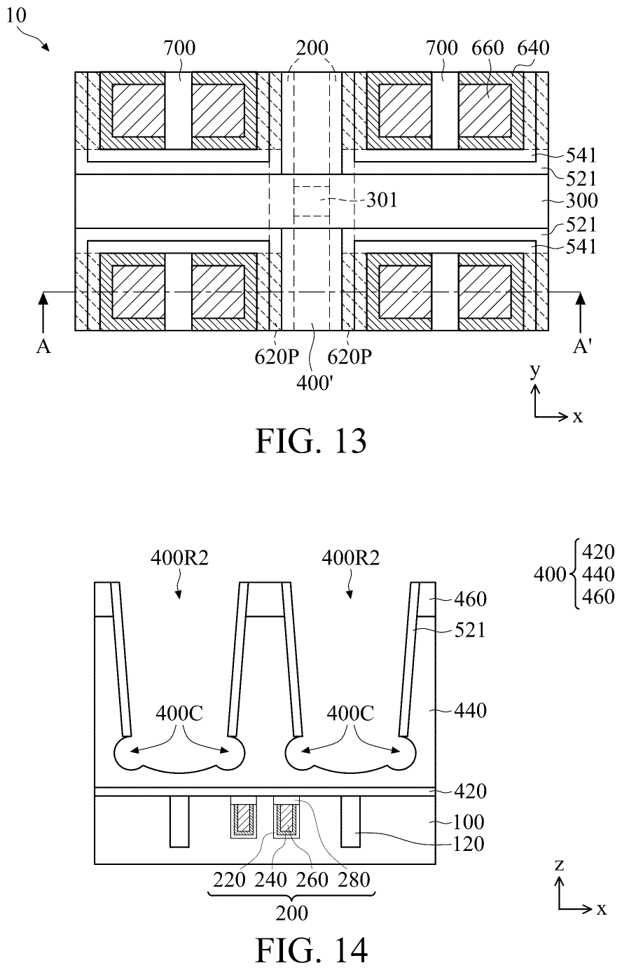

Referring to FIGS. 11-13, the capacitor-based memory 10 may include an isolation structure 700 penetrating through the capacitor contact material, so the capacitor contact material located in each through hole 400T2 may be separated into two independent capacitor contacts 600, according to an embodiment. FIG. 11 is the cross-sectional view obtained from a line A-A′ of FIG. 13. The location of the isolation structure 700 may overlap the location of the shallow trench isolation structure 120 in the vertical projection. In the cross-sectional view parallel with the extending direction of the bit lines 300 (for example, the line A-A′ shown in FIG. 13), after the formation of the isolation structure 700, each capacitor contact 600 may have a single-sided protruding portions 620P embedded into the insulating structures 400′, and a planar sidewall adjoining with the isolation structure 700 on another side. From another perspective, the opposing sidewalls of each insulating structure 400′ located between neighboring isolation structures 700 both have the cavities 400C. In other words, the opposing sides of each capacitor contact 600 may be asymmetrical, and the opposing sides of each insulating structure 400′ may be symmetrical. Materials of the isolation structure 700 may be similar to those of the shallow trench isolation structure 120. Each capacitor contact 600 is configured to electrically connect the overlying capacitor (not shown) with the underlying substrate 100. According to a preferred embodiment, the top surface of the capacitor contacts 600 may be levelled with the top surfaces of the insulating structures 400′ and the isolation structure 700, so the manufacturing yield of the overlying capacitor may be enhanced.

In FIGS. 12 and 13, in addition to the substrate 100, the shallow trench isolation structure 120, the word lines 200, the insulating structures 400′, the capacitor contacts 600, the first dielectric layer 521, the second dielectric layer 541, and the isolation structure 700 stated above, the capacitor-based memory 10 of the present disclosure may further include the bit lines 300 and a bit line contact structure 301. The extending direction of the bit lines 300 (for example, in x-axis) may be different from the extending direction of the word lines 200 (for example, in y-axis). It is worth noted that the extending direction of the protruding portions 620P may be parallel with the extending direction of the bit lines 300 (for example, in x-axis), and the protruding portions 620P may be embedded into the insulating structures 400′. The bit line contact structure 301 may be disposed for example on the substrate 100 between neighboring word lines 200, for electrically connecting the substrate 100 with the bit lines 300. The bit line contact structure 301 may be formed using any known process, structure, or material. In a preferred embodiment, the bit line contact structure 301 may not overlap the word lines 200 in the vertical projection, thus the interference between the bit line contact structure 301 and the word lines 200 may be reduced even further, which is advantageous for miniaturization.

In some embodiments, the bit lines 300 and the bit line contact structure 301 may first be formed before the formation of the insulating structures 400′. The insulating structures 400′ and the capacitor contacts 600 may be alternately arranged on the opposing sides of each bit line 300 along the extending direction of the bit lines 300 (for example, in x-axis). The insulating structures 400′ and the capacitor contacts 600 may be self-aligned and filled into the space between neighboring bit lines 300. Therefore, the capacitor contacts 600 may also be referred to as self-aligned contacts (SAC). The bit lines 300 may include a dielectric layer 320, a conductive layer 340, and a hard mask 360 sequentially formed on the substrate 100 and the bit line contact structure 301, as well as a spacer 380 formed on the sidewalls of the dielectric layer 320, the conductive layer 340, and the hard mask 360. Materials of the dielectric layer 320 may be similar to those of the dielectric layer 220. Materials of the conductive layer 340 may be similar to those of the conductive filling 260. Materials of the hard mask 360 may be similar to those of the capping layer 280. Materials of the spacer 380 may be selected from low-k materials, such as oxides, silicon nitride, silicon oxynitride, silicon carbonitride, silicon oxynitrocarbide, air gap, or a combination thereof.

Referring to FIG. 12, the bit lines 300 may be exposed after the formation of the through hole 400T2. Therefore, the first dielectric layer 521 and the second dielectric layer 541 may be disposed between the bit lines 300 and the capacitor contacts 600, for example, between the spacer 380 and the capacitor contacts 600. In doing so, the parasitic capacitance between the bit lines 300 and the capacitor contacts 600 may be reduced. Furthermore, even if the thickness of the spacer 380 needs to be reduced for miniaturization, the interference between the bit lines 300 and the capacitor contacts 600 may still be reduced due to the additional second dielectric layer 541 disposed between the spacer 380 and the capacitor contacts 600 in the present disclosure.

In some preferred embodiments, the bottom surface of the first dielectric layer 521 is lower than the bottom surface of the conductive layer 340 of each bit line 300, in order to further reduce the parasitic capacitance between the bit lines 300 and the capacitor contacts 600. Furthermore, the capacitor contacts 600 may not overlap both the bit line contact structure 301 and the bit lines 300 in the vertical projection. In other words, the capacitor contacts 600 may be separated from the bit line contact structure 301 and the bit lines 300. Such configuration may further reduce the interference, and may be advantageous for the structural stability of the bit line contact structure 301 and the bit lines 300, thus the manufacturing yield may be enhanced.

Referring to FIG. 13, since the word lines 200 are embedded into the substrate 100, and the protruding portions 620P are embedded into the insulating structures 400′, the word lines 200 and the protruding portions 620P are denoted with dash lines. In an embodiment, the protruding portions 620P may overlap the word lines 200 in the vertical projection, which is advantageous for miniaturization.

In the above embodiments, the first dielectric layer 521 may first be formed, followed by the formation of the through hole 400T2 and the cavities 400C, and the second dielectric layer 541 may be formed on the surfaces of the through hole 400T2 and the cavities 400C. FIGS. 14-17 illustrate cross-sectional views of various intermediate stages of manufacturing a capacitor-based memory 20, according to another embodiment of the present disclosure. Referring to FIG. 14, after performing the procedures of FIGS. 1-4 (for example, after the formation of the first dielectric layer 521), the insulating material layer 400 below the recess 400R1 may be etched using the first dielectric layer 521 as the mask, so the recess 400R1 may be extended downward to become a recess 400R2 not exposing the substrate 100. The cavities 400C may be formed at the bottom portion of the sidewalls of the recess 400R2 exposed through the first dielectric layer 521.

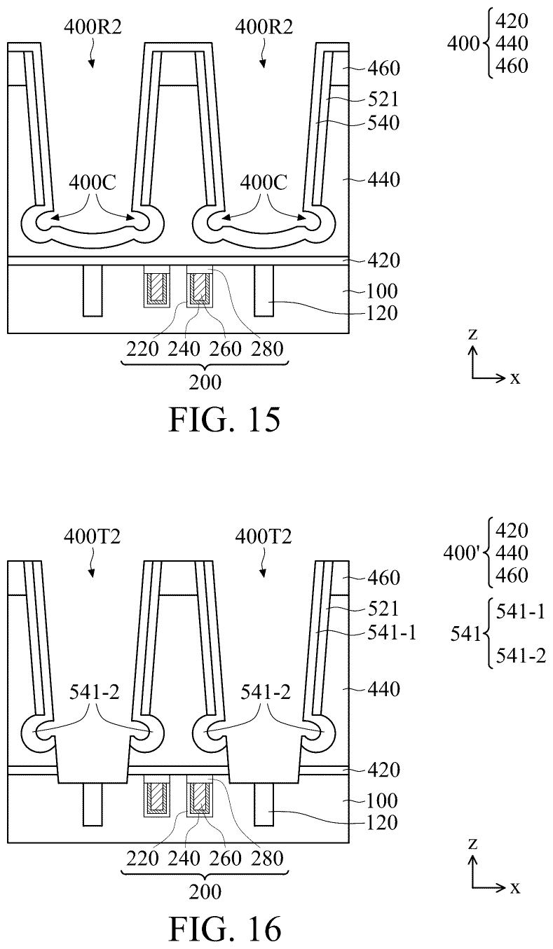

Referring to FIG. 15, the second dielectric material 540 may be formed. In addition to lining onto the surfaces of the recess 400R2 and the cavities 400C, the second dielectric material 540 may also be conformally formed on the top surface of the insulating material layer 400.

Referring to FIG. 16, the horizontal portions of the second dielectric material 540 may be removed to form the second dielectric layer 541. Next, the insulating material layer 400 below the recess 400R2 may be removed using the second dielectric layer 541 as the mask, so the recess 400R2 may be extended downward to become the through hole 400T2 exposing the substrate 100. Furthermore, the etched insulating material layer 400 becomes the insulating structures 400′. In doing so, the bottom portion of the sidewalls of the through holes 400T2 is free of the first dielectric layer 521 and/or the second dielectric layer 541. In some preferred embodiments, the bottom surface of the second dielectric layer 541 may be lower than the bottom surface of the conductive layer 340 of each bit line 300, in order to further reduce the parasitic capacitance between the bit lines 300 and the capacitor contacts 600. In some preferred embodiments, the thickness of the second dielectric layer 541 may be greater than the thickness of the first dielectric layer 521, in order to further reduce the parasitic capacitance between the bit lines 300 and the capacitor contacts 600. After that, the recessing of the substrate 100 may be performed.

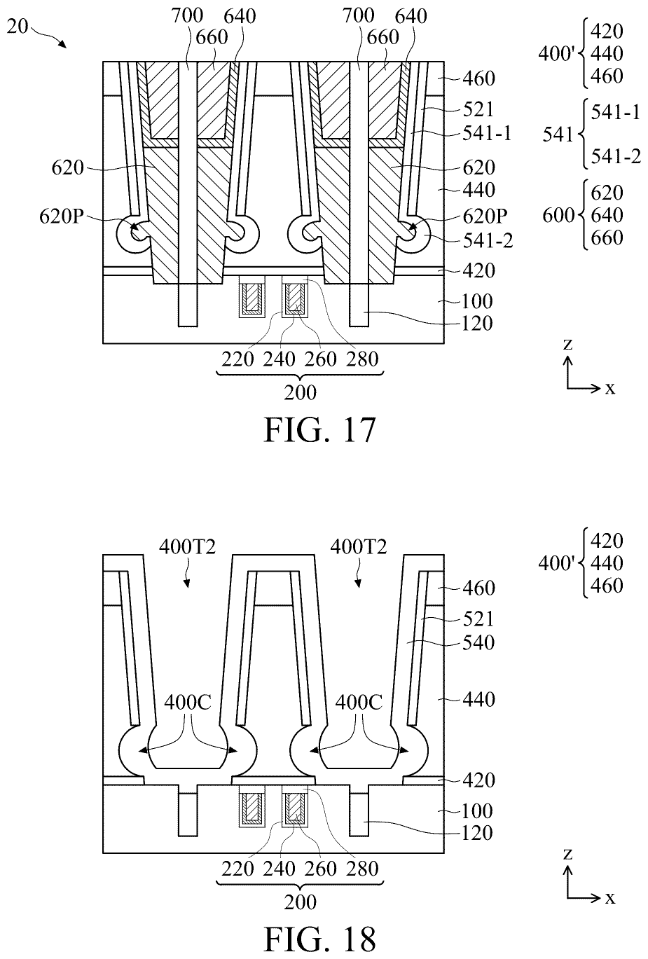

Referring to FIG. 17, the capacitor contacts 600 (including the protruding portions 620P) and the isolation structure 700 may be formed in the through hole 400T2. It should be noted that the remaining details in the present embodiment not specifically described may be similar to those illustrated in the embodiment of the capacitor-based memory 10, and the details are not described again herein to avoid repetition.

In the above embodiments, the illustrated second dielectric material 540 does not fill the cavities 400C. FIGS. 18-20 illustrate cross-sectional views of various intermediate stages of manufacturing a capacitor-based memory 30, according to yet another embodiment of the present disclosure. Referring to FIG. 18, after performing the procedures of FIGS. 1-6, the second dielectric material 540 may be deposited in the through hole 400T2 and the cavities 400C. The cavities 400C may be filled with the second dielectric material 540.

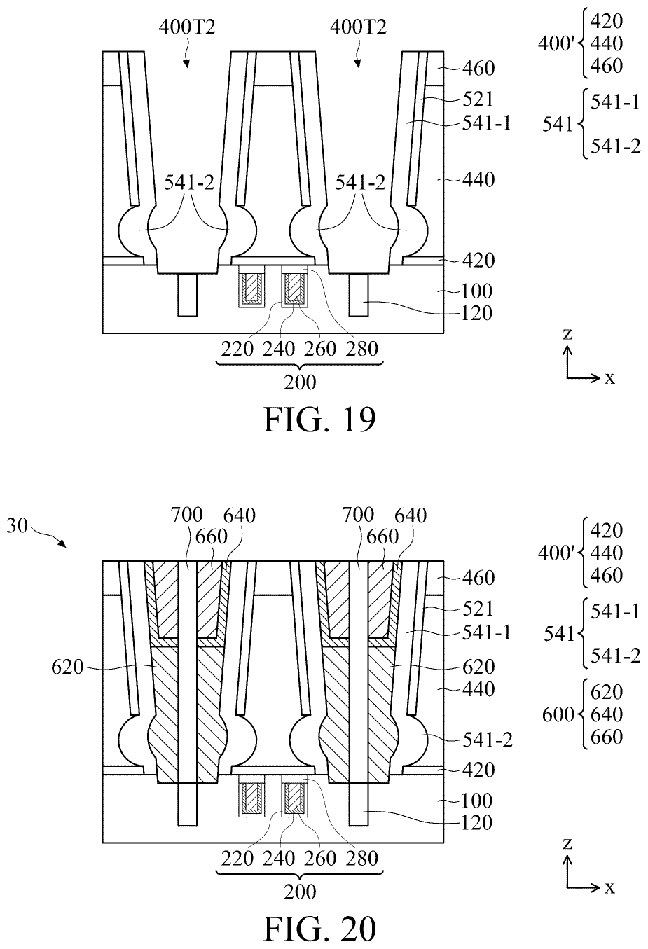

Referring to FIG. 19, the horizontal portions of the second dielectric material 540 may be removed to form the second dielectric layer 541. In a specific embodiment of the present disclosure, the cavities 400C may be substantially filled with the second portion 541-2 of the second dielectric layer 541.

Referring to FIG. 20, the capacitor contacts 600 and the isolation structure 700 may be formed in the through hole 400T2. Since the cavities 400C have been substantially filled by the second portion 541-2 of the second dielectric layer 541, the capacitor contacts 600 of the capacitor-based memory 30 do not have the protruding portions 620P filling the cavities 400C. Such design may reduce the generation of voids during the filling of the conductive material 620 into the cavities 400C. It should be noted that the remaining details in the present embodiment not specifically described may be similar to those illustrated in the embodiment of the capacitor-based memory 10, and the details are not described again herein to avoid repetition.

According to the capacitor-based memory and the method of manufacturing the same of the present disclosure, the first dielectric material may be formed in the recess that does not penetrate through the insulating material layer during the manufacturing of the capacitor contacts. The insulating material layer below the recess may be etched using the first dielectric layer as the mask, so the recess may be extended downward to become the deeper recess, or the through hole that exposes the substrate. Next, the cavities may be formed at the bottom portion of the sidewalls of the deeper recess or the through hole exposing the substrate, and the second dielectric layer may be formed in the cavities. The cavities may or may not be completely filled with the second dielectric layer. In doing so, the second dielectric layer in the cavities may not be damaged from the subsequent etching process, and the subsequently formed capacitor contacts may have the protruding portions filling the cavities (if the cavities are not filled by the second dielectric layer). If the protruding portions directly contact the substrate, the contact area between the capacitor contacts and the substrate may be further increased, thereby reducing the contact resistance and enhancing the reliability of the capacitor-based memory. Other advantages associated with the present disclosure have been clearly explained in the above embodiments, and the details are not described again herein to avoid repetition.

The present disclosure may be suitable for manufacturing a scaled capacitor-based memory to increase the total quantity of dies on the wafer. Therefore, the present disclosure may reduce the production cost and the power consumption of manufacturing and subsequently packaging a single integrated circuit (IC), thereby reducing the carbon emission during the production of the capacitor-based memory. Furthermore, in the capacitor-based memory of the present disclosure, the manufacturing yield of the capacitor-based memory may be improved because the unintentional bridging or crosstalk between the capacitor contacts has been prevented. In some preferred embodiments, the contact resistance of the capacitor contacts can be reduced, the interference between the capacitor contacts and the bit line contact structure and the interference between the capacitor contacts and the bit lines may be reduced. Therefore, the present disclosure may enhance the sensing margin, thereby reducing the power consumption and increasing the operating speed, which may be ideal for low power consumption products. As a result, the present disclosure provides a green semiconductor technology.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor-based memory, comprising:
a substrate;
bit lines disposed on the substrate;
insulating structures disposed on the substrate and located between neighboring bit lines, wherein a bottom portion of each insulating structure has two cavities facing each other along an extending direction of each bit line;
a capacitor contact disposed on the substrate and located in a through hole between neighboring insulating structures;
a first dielectric layer disposed on a sidewall of the through hole above the cavities and located between each insulating structure and the capacitor contact; and
a second dielectric layer, comprising:
a first portion disposed on the first dielectric layer and located between the first dielectric layer and the capacitor contact; and
a second portion disposed in the cavities and located between the bottom portion of each insulating structure and the capacitor contact.

2. The capacitor-based memory of claim 1, further comprising:
an isolation structure disposed in the through hole and separates two of the capacitor contacts in the through hole; and
a shallow trench isolation structure disposed in the substrate.

3. The capacitor-based memory of claim 2, wherein each capacitor contact comprises a conductive material filled into each cavity to form a single-sided protruding portion embedded in each insulating structure.

4. The capacitor-based memory of claim 3, wherein the single-sided protruding portion directly contacts the substrate.

5. The capacitor-based memory of claim 3, wherein an extending direction of the single-sided protruding portion is parallel with the extending direction of each bit line.

6. The capacitor-based memory of claim 2, wherein a location of the isolation structure overlaps a location of the shallow trench isolation structure in a vertical projection.

7. The capacitor-based memory of claim 1, wherein a maximum horizontal depth from an extending line of a main surface of the first dielectric layer to a surface of the cavities is smaller than half of a maximum width of each insulating structure and greater than 5% of the maximum width of each insulating structure.

8. The capacitor-based memory of claim 2, further comprising:
word lines disposed in the substrate; and
a bit line contact structure located on the substrate between neighboring word lines.

9. The capacitor-based memory of claim 8, wherein each bit line comprises a dielectric layer, a conductive layer, and a hard mask sequentially disposed on the substrate, and a spacer formed on sidewalls of the dielectric layer, the conductive layer, and the hard mask, wherein the first dielectric layer and the second dielectric layer are located between the spacer and the capacitor contact.

10. The capacitor-based memory of claim 9, wherein a bottom surface of the first dielectric layer is lower than a bottom surface of the conductive layer.

11. The capacitor-based memory of claim 8, wherein the capacitor contact is separated from the bit line contact structure and each bit line.

12. The capacitor-based memory of claim 3, further comprising:
word lines disposed in the substrate,
wherein the single-sided protruding portion overlaps the word lines in a vertical projection.

13. The capacitor-based memory of claim 9, wherein a bottom surface of the second dielectric layer is lower than a bottom surface of the conductive layer of each bit line, and the bottom surface of the second dielectric layer is higher than a top surface of the substrate.

14. The capacitor-based memory of claim 1, wherein a thickness of the second dielectric layer is greater than a thickness of the first dielectric layer.

15. The capacitor-based memory of claim 14, wherein the second portion of the second dielectric layer fills the cavities.

16. A method of manufacturing a capacitor-based memory, comprising:
forming bit lines on a substrate;
forming insulating structures on the substrate between neighboring bit lines, wherein a bottom portion of each insulating structure has two cavities facing each other along an extending direction of each bit line;
forming a capacitor contact on the substrate in a through hole between neighboring insulating structures;
conformally forming a first dielectric layer on a sidewall of the through hole above the cavities and between each insulating structure and the capacitor contact; and
forming a second dielectric layer, comprising a first portion and a second portion, wherein the first portion is formed on the first dielectric layer between the first dielectric layer and the capacitor contact, wherein the second portion is formed in the cavities between the bottom portion of each insulating structure and the capacitor contact.

17. The method of claim 16, wherein forming the insulating structures further comprising:
forming an insulating material layer on the substrate;
forming a recess in the insulating material layer, wherein a bottom surface of the recess is higher than a bottom surface of the insulating material layer, and the recess is between neighboring bit lines, wherein the first dielectric layer is conformally formed on sidewalls of the recess;
after the first dielectric layer is conformally formed, etching the insulating material layer below the recess to form the cavities in a bottom portion of the insulating material layer; and
extending the recess downward to become the through hole exposing the substrate, and the insulating material layer becomes the insulating structures.

18. The method of claim 17, wherein a depth of the recess is greater than or equal to half of a thickness of the insulating material layer.

19. The method of claim 17, further comprising:
recessing the substrate after forming the second dielectric layer; and
etching the insulating material layer below the recess using the first dielectric layer as a mask, wherein the cavities are formed at a bottom portion of sidewalls of the through hole exposed by the first dielectric layer.

20. The method of claim 17, further comprising:
recessing the substrate after forming the second dielectric layer;
etching the insulating material layer below the recess using the first dielectric layer as a mask to extend the recess downward to become a deeper recess not exposing the substrate, and the cavities are formed at a bottom portion of sidewalls of the deeper recess exposed by the first dielectric layer; and
etching the insulating material layer below the deeper recess using the second dielectric layer as a mask to extend the deeper recess downward to become the through hole exposing the substrate, and the insulating material layer becomes the insulating structures.
